(19) United States
(12) Patent Application Publication
(10) Pub. No.: US 2007/0018534 A1
(43) Pub. Date: Jan. 25, 2007

(54) Method and apparatus for monitoring and evaluating operation of a piezoelectric actuator

(76) Inventors: Giacomo Sciortino, Osnabrueck (DE); Christopher Andrew Goat, Offham (GB)

Correspondence Address: DELPHI TECHNOLOGIES, INC., M/C 480-410-202, PO BOX 5052, TROY, MI, 48007, US

(21) Appl. No.: 11/489,823

(22) Filed: Jul. 20, 2006

(30) Foreign Application Priority Data
Jul. 22, 2005 (EP) 05015988.8

(51) Int. Cl. H01L 41/107

(52) U.S. Cl. 310/316.01

(57) ABSTRACT

The invention relates to a method for the monitoring and evaluation of the operation of a piezoelectric actuator, wherein electrical discharging and charging processes of the actuator are monitored and the operation of the actuator is evaluated with reference to the time course of the discharging and charging processes. The invention further relates to an apparatus for the carrying out of the method.

### TECHNICAL FIELD

The invention relates to a method and to an apparatus for monitoring and evaluating operation of a piezoelectric actuator.

### BACKGROUND OF THE INVENTION

Piezoelectric actuators are generally known and are used, for example, in fuel injection valves, so-called piezoelectric injectors, to control the supply of fuel into the combustion chamber of a combustion engine, e.g. of a motor vehicle.

A known piezoelectric actuator comprises a package of typically several hundred ceramic layers stacked over one another and having piezoelectric properties. Individual ceramic layers can be expanded by some tenths of a micrometer by application of a corresponding electrical charge, whereby the total piezo package expands by several hundredths of a millimeter depending on the number of the ceramic layers stacked over one another. This cumulative expansion of the stack can be sufficient to raise a valve needle of a piezoelectric injector from its valve seat and to sufficiently open the valve to permit a metered flow through the valve.

Up to now, the examination of damaged piezoelectric actuators has proven to be problematic since defective piezoelectric actuators were only able to be recognized as defective after a final failure.

The final failure of the piezoelectric actuator often results from an excessive local heat development, in particular at that position at which the defect has its origin. Due to the local heat development, the ceramic layers adjacent to the defect position can be melted or passivation layers arranged at the surface of the ceramic layers and/or a jacket of the piezo package can be carbonized, whereby the original defect position is totally destroyed. In this manner, not only information on the cause for the failure of the piezoelectric actuator, i.e. on the original defect, but also details on the time development of the damage are destroyed. A piezoelectric actuator destroyed by heat development can even be so severely damaged that it may no longer be possible to determine where the defect of the actuator was triggered, e.g., at its surface or in its interior.

### SUMMARY OF THE INVENTION

It is the underlying object of the invention to provide a method and an apparatus for the monitoring and evaluation of the operational capability of a piezoelectric actuator which permits a recognition of an error of a piezoelectric actuator as early as possible.

A method and an apparatus in accordance with the independent claims are provided to satisfy the object.

In the method in accordance with the invention for monitoring and evaluating the operation of a piezoelectric actuator, electrical discharging and charging processes of the actuator are monitored and the operation of the actuator is evaluated with reference to the time course of the discharging and charging processes.

A deviation of the process of a monitored discharging or charging process from a discharging or charging process of a defect-free actuator to be expected provides an indication of a defect in the actuator. It has been found in this process that even those defects already effect a noticeable modification of the time course of the discharging and charging processes which do not, or at least do not immediately, result in a final failure of the actuator.

An early error recognition is therefore possible with the method in accordance with the invention. A defective actuator can thereby already be deactivated before its complete destruction and the defect and in particular its cause can be analyzed in detail. Alternatively or additionally, the time development of the defect up to a complete destruction of the actuator can be examined. A detailed examination of this type of the formation and development of a defect of the piezoelectric actuator permits future piezoelectric actuators to be modified such that the error found is largely avoided. The result is that piezoelectric actuators can thereby be provided which have an increased reliability and service life.

Furthermore, the method cannot only be used for error analysis, but also for the monitoring of a piezoelectric actuator during its intended use. If the actuator is a component of a piezoelectric injector of a motor vehicle combustion engine, the method can, for example, be used to warn a driver of the motor vehicle as early as possible before a failure of the actuator or of the injection valve and so to permit an exchange in good time.

In accordance with a particularly advantageous embodiment of the method in accordance with the invention, an electrical pulse current is applied to the actuator, the time course of an electrical voltage falling over the actuator is determined, the wave shape of the determined voltage curve is compared with a desired wave shape to be expected with a problem-free operation of the actuator and the operation of the actuator is evaluated with reference to the comparison of the wave shape of the determined voltage curve with the desired wave shape.

Investigations have shown that the occurrence of a defect in the actuator as a rule results in a deviation of the wave shape of the determined voltage curve from the desired wave shape. An aspect of the invention therefore consists of monitoring the time course of the voltage falling over the actuator and using it as an indicator for the operational state of the actuator. In this process, a defect-free operation of the piezoelectric actuator is assumed as long as the wave shape of the determined voltage curve coincides with the desired wave shape, whereas a deviation of the wave shape of the determined voltage curve from the desired wave shape is evaluated as an early indication of the start of a defective operation of the piezoelectric actuator.

As soon as a malfunction of the piezoelectric actuator is determined, the power supply to the actuator can be switched off and further damage to the actuator can thus be prevented. This permits an in-depth examination of the piezoelectric actuator with respect to the cause of the malfunction and, optionally, a replacement of the actuator before it is e.g. completely destroyed by an excessive heat development.

On a subsequent continuation of the operation of the actuator by a repeated application of the pulse current and on a further observation of the recorded voltage as well as a further examination of the actuator, the development of the defect up to a complete destruction of the actuator can be analyzed.

The type of damage to the actuator can be concluded from the type of a deviation of the wave shape of the determined voltage curves from the desired wave shape. The fact is utilized here that specific defects cause a characteristic modification of the wave shape of the voltage falling over the actuator.

For example, a surface short-circuit and an internal short-circuit of the piezoelectric actuator result in different changes of the wave shape of the voltage falling over the actuator. It is generally even possible to distinguish or identify different error sources within the group of surface short-circuits or of internal short-circuits.

It is furthermore possible to determine damage resulting from material fatigue of e.g. an external electrode of the piezoelectric actuator in the form of a metal strip. Material fatigue of this type typically results in an at least part separation of the electrode from the piezo package, whereby the actuator can only be partly charged. The reduction in the capacity of the actuator resulting from this leads to an increase in the charging speed. The latter means a faster voltage change and is expressed in a steeper steepness of the flank of the voltage pulse.

It is preferred for a pulse width modulated current to be applied to the actuator. On an operation of the actuator for test purposes, this permits a precise simulation of the current/voltage conditions occurring on the intended use of the actor. Furthermore, the pulse width modulation of the current applied to the actuator permits a charging of the actuator with a precisely predetermined number of discrete charge packages by which a specific voltage falling over the actuator is achieved. A deviation of the relationship between the number of charge packages and the achieved voltage provides an indication of a defect of the piezoelectric actuator.

The actuator is first discharged by a current pulse and is then charged again in a defined manner. The charge applied is held in the actuator during the time lying between two pulses. In this charged state, the piezo package is expanded so that, for example, a valve needle of an injection valve is held on the associated valve seat. The actuator reacts particularly sensitively to defects between two current pulses, i.e. when the electrical charge is stored in the actuator.

A change in the voltage falling over the actuator between two current pulses provides an indication of an electrical short circuit or a self-discharge of the actuator. An increase in the number of charge packages required for the reaching of a target voltage between two current pulses furthermore indicates an electrical short circuit or a self-discharge of the actuator since the last charge movement event. Vice versa, a reduction of the number of charge packages required for the reaching of the target voltage provides an indication of an at least part separation of a part of the piezo package.

Alternatively or additionally to the monitoring of the voltage curve, the time development of a leakage current of the actuator can also be determined and the operation of the actuator can be evaluated with reference to the frequency of increased leakage currents.

Experience has admittedly shown that leakage currents also occur occasionally with a piezoelectric actuator operating without problem. It has, however, been found that the frequency and/or the strength of the leakage currents increases or increase when a piezoelectric actuator has a defect. Consequently, a malfunction of the actuator can also be determined with reference to a significant accumulation and/or a significant increase of leakage currents of the actuator.

The probability that a defect is recognized early and, is optionally even identified correctly, is substantially increased by a simultaneous monitoring of the voltage falling over the actuator and of the leakage currents.

The time course of the determined voltage and/or of the determined leakage current of the actuator is/are preferably stored in a storage medium. This permits a precise analysis of the time development of a defect in the actuator even at a later point in time.

In accordance with a further embodiment, with a predetermined form of a deviation of the determined wave shape from the desired wave shape and/or on an exceeding of a predetermined frequency and/or strength of an increased leakage current of the actuator, a warning signal is output. This permits an early warning of an impending failure of the piezoelectric actuator.

In this process, the predetermined deviation of the recorded wave shape or the predetermined frequency or strength of the leakage current, which results in a triggering of the warning, can be selected such that a deactivation and/or a replacement of the defective piezoelectric actuator is possible before it is completely destroyed. If, for example, the actuator is part of a piezoelectric injection valve of a motor vehicle combustion engine, the driver of the motor vehicle can thus be made aware of the defect in good time so that a replacement of the piezoelectric actuator is possible before the engine performance is noticeably influenced.

The apparatus in accordance with the invention serves the carrying out of the method in accordance with the invention and thus permits the achieving of the aforesaid advantages.

### BRIEF DESCRIPTION OF THE DRAWINGS

The invention will be described in the following purely by way of example with reference to an advantageous embodiment and to the drawing. There are shown:

FIG. 1 is a schematic representation of an apparatus in accordance with the invention for the monitoring and evaluation of the operational capability of a piezoelectric actuator;

FIG. 2 is the wave shape of a voltage which falls over a piezoelectric actuator to which a pulse width modulated current is applied;

FIG. 3 is the effect of a self-discharge on the wave shape of a voltage which falls over a piezoelectric actuator driven by pulse width modulation; and

FIG. 4 is the time development of the leakage current of a piezoelectric actuator which failed after 856 operating hours.

### DESCRIPTION OF THE PREFERRED EMBODIMENT

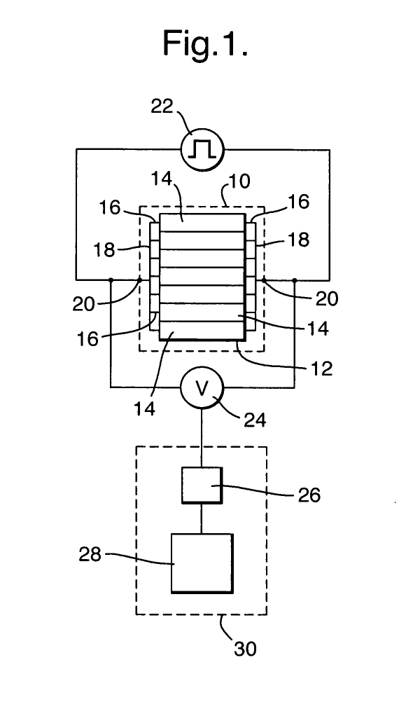

In FIG. 1, an apparatus in accordance with the invention for the monitoring and evaluation of the operation of a piezoelectric actuator 10 is shown.

The actuator 10 comprises a piezo package 12 which is formed from several hundred ceramic layers 14 which are stacked over one another and of which only seven are shown by way of example in the Figure. Each ceramic layer 14 is connected via two electrodes 16 to two collector electrodes 18 which are in turn each connected to an external connection 20 of the actuator 10.

The actuator 10 is connected via the connections 20 to a power source 22 which delivers a pulse width modulated pulse current to the actuator 10.

On a use of the actuator 10 in a piezoelectric injection valve of a motor vehicle combustion engine, the pulse width can amount to approximately 0.4 ms and make up 5% of a cycle time so that the time between two current pulses amounts to 95% of the cycle time and thus to approximately 0.7 s.

The electrical voltage falling over the actuator 10 and in particular falling over the piezo package 12 is measured continuously by means of a voltage measurement device 24. The voltage values determined are transmitted to a comparator unit 26 in which the time development of the measured voltage values, i.e. the wave shape of the recorded voltage, is compared with a desired wave shape which is to be expected with a problem-free operation of the actuator 10. For this purpose, the comparator unit 26 has a storage unit (not shown) in which the wave shape of the voltage falling over the actuator 10 to be expected in each case for the respective pulse width modulated current applied to the actuator 10 is stored.

As soon as a deviation of the recorded wave shape from the desired wave shape is detected by the comparator unit 26, the comparator unit 26 outputs a corresponding signal to an evaluation unit 28 in which an evaluation of the deviation of the recorded wave shape from the desired wave shape takes place, for example with respect to the type, the strength and/or the frequency of the deviation.

If the detected deviation exceeds a predetermined significance threshold, a corresponding warning signal can be output by the evaluation unit 28 to draw attention to a defective operation of the actuator 10 and/or to warn of a failure of the actuator 10.

As is shown in FIG. 1, the comparator unit 26 and the evaluation unit 28 are combined together in one computing unit 30. It is, however, generally also possible to provide the comparator unit 26 and the evaluation unit 28 as separate units in each case. The computing unit 30 can furthermore comprise a storage medium (not shown) in which the time development of the voltage falling over the actuator 10 is stored over a predetermined time period, e.g. over the whole operating period of the actuator 10.

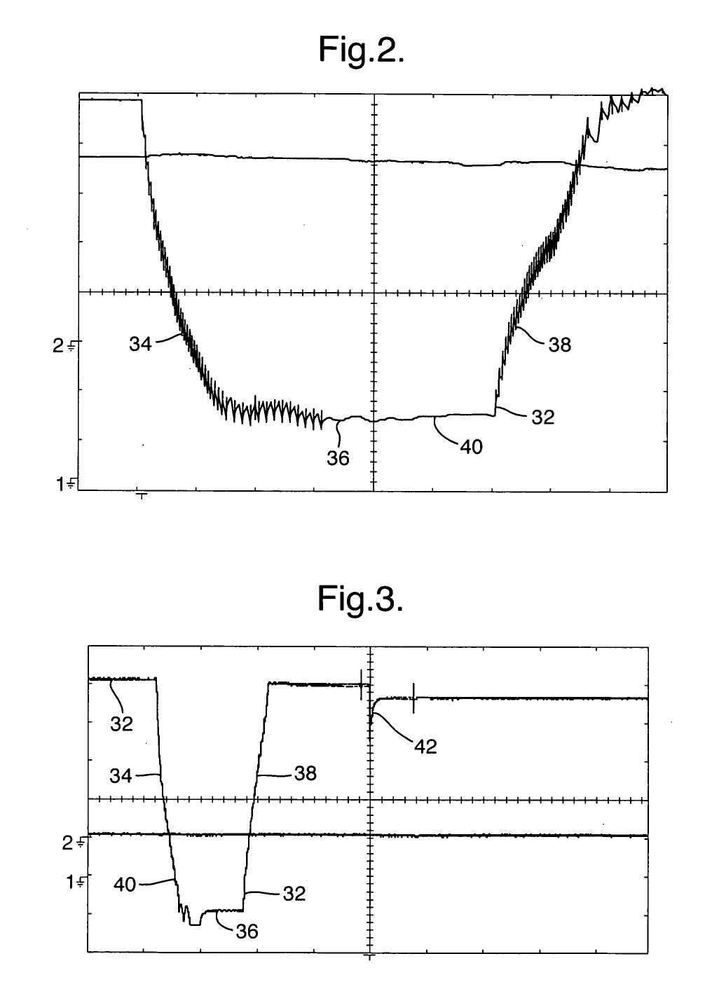

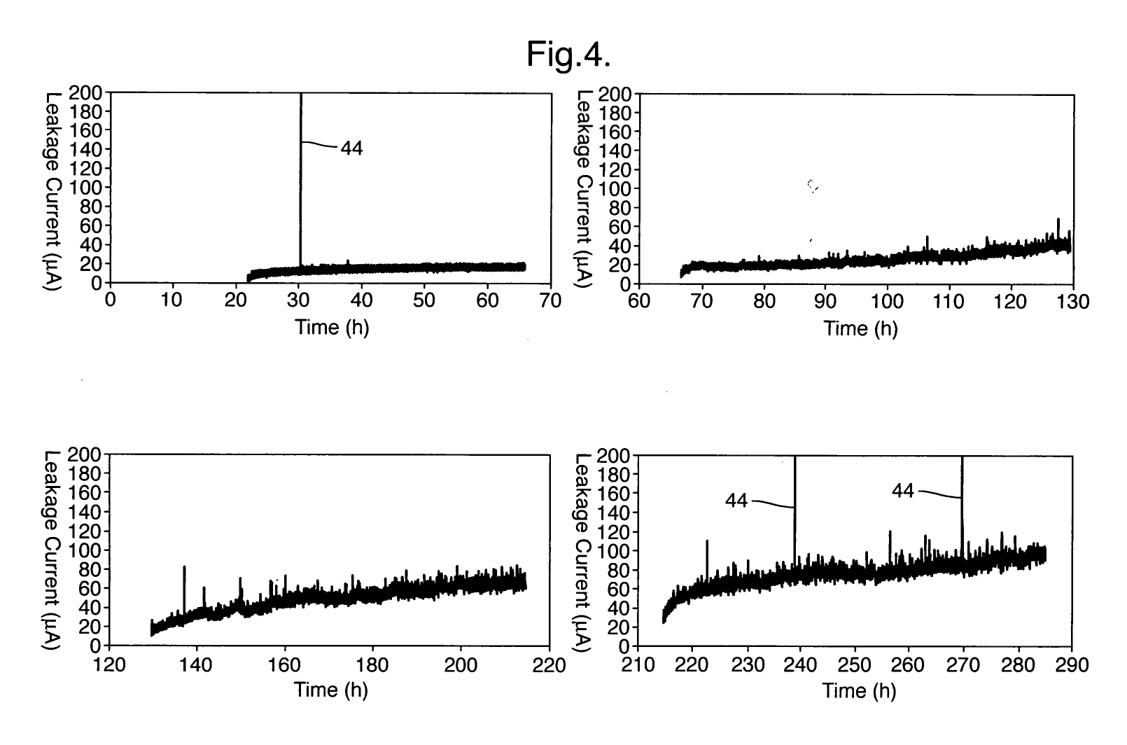

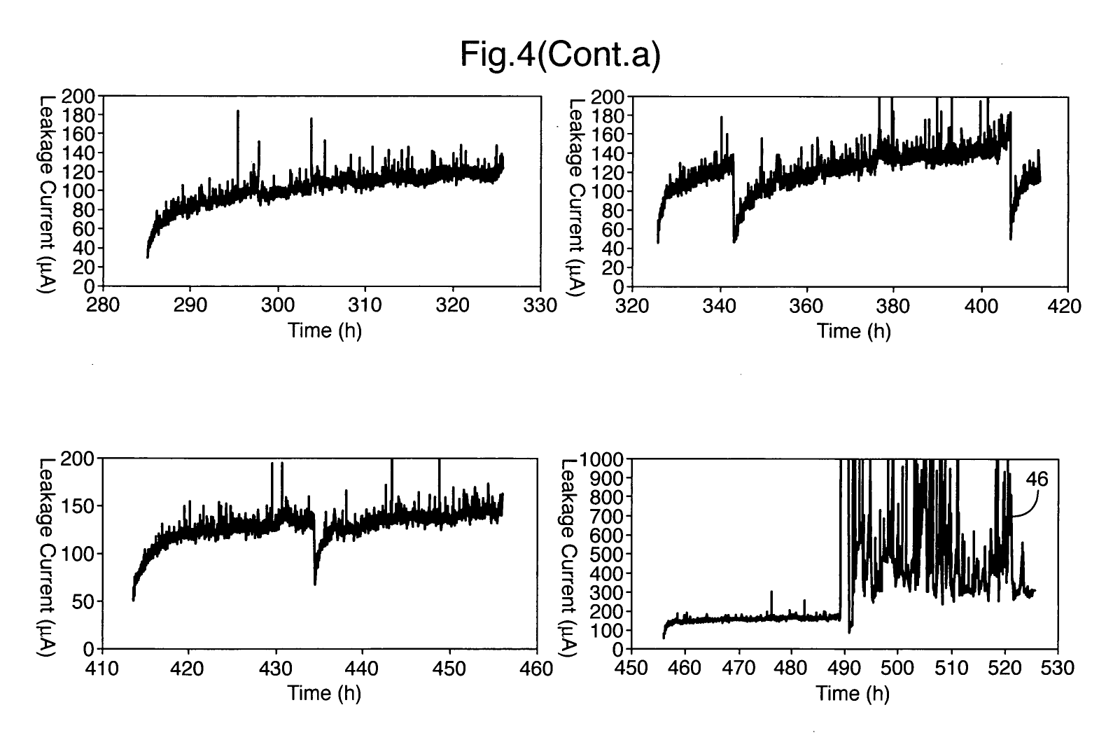

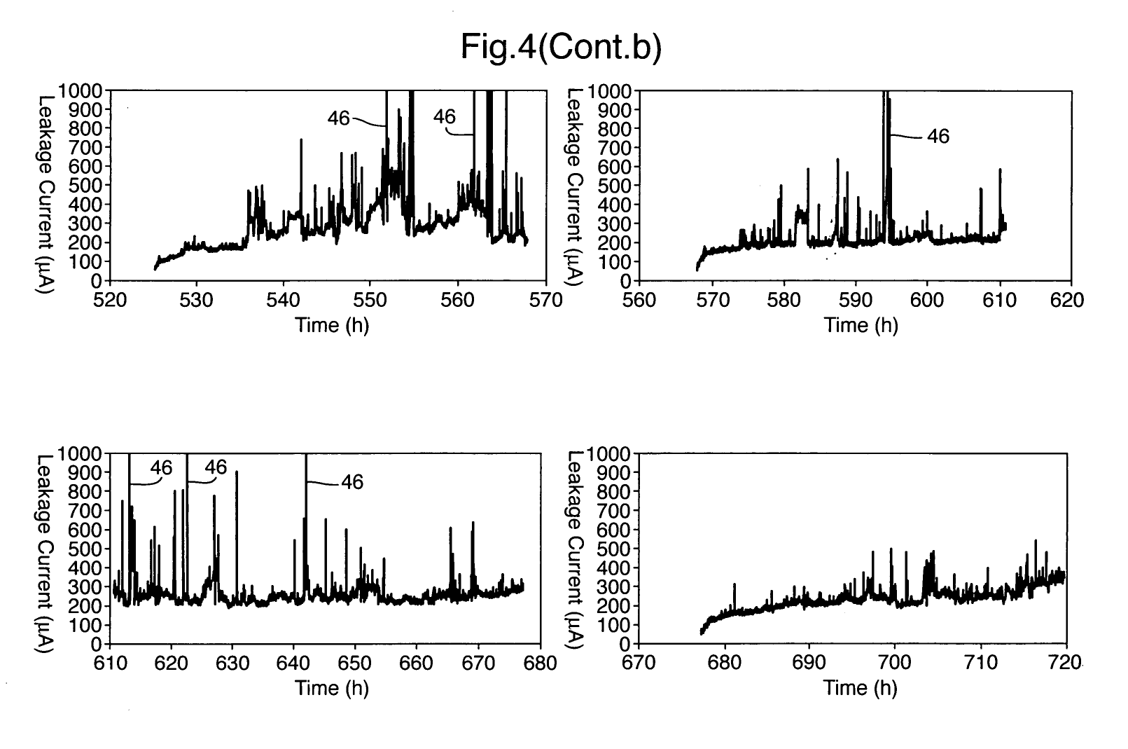

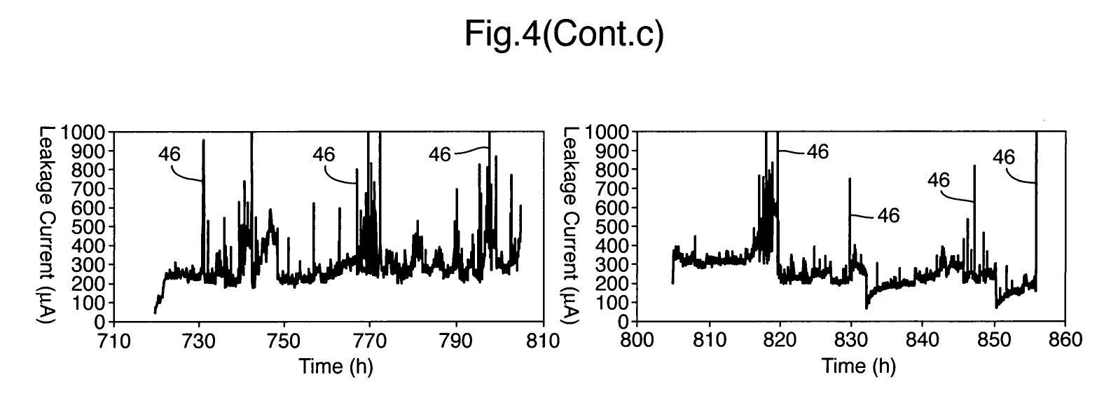

In FIG. 2, the wave shape 32 of the voltage falling over the actuator 10 during a current pulse output by the power source 22 is shown. The measured voltage is entered as a function of time.

The actuator 10 is first electrically discharged by the current pulse (left hand falling flank 34 of the wave shape 32), then held in the discharged state for a specific time (plateau 36 of the wave shape 32) and finally electrically charged again (right hand rising flank 38 of the wave shape 32). The result is therefore a voltage pulse 40 whose shape is dependent on the shape of the current pulse.

The discharge of the actuator 10 has the effect that the actuator 10 can adopt its non expanded normal state and can thereby, for example, raise a valve needle from its valve seat to permit an injection of fuel into a combustion chamber. The subsequent electrical charge of the actuator 10 effects a renewed expanding of the actuator 10, whereby the valve needle is again pressed onto its valve seat and the fuel injection is ended.

Since the piezoelectric actuator 10 forms an electrical resonant circuit due to its capacitive and inductive properties, the electrical discharging or charging of the actuator 10 takes place by an alternating application and discharging of charge packages to and from the actuator 10 respectively in the form of short current pulses. These charge packages, which move to and fro, are expressed in the form of a saw tooth pattern which is superimposed on the falling flank and on the rising flank of the wave shape 32 of the recorded voltage.

The shape of the saw tooth pattern can be used, in addition to the steepness of the falling or rising flanks 34, 38 of the voltage pulse 40, for the evaluation of the operation of the piezoelectric actuator 10.

An increase in the number of charge pulses required to achieve a specific target voltage can thus suggest an electrical short-circuit or a leakage current which has occurred since the last charge movement event. Vice versa, a reduction in the number of charge pulses required to achieve a specific target voltage can provide an indication of a mechanical peeling of ceramic layers 14 from the remaining part of the piezo package 12.

An increased steepness of the falling or rising flank 34, 38 is an indication of a reduced capacity of the actuator 10 which can be caused in that only a part of the actuator 10 is electrically discharged or charged. This only part discharging or charging of the actuator can, for example, result from damage to one or more electrodes 16, e.g. due to material fatigue.

In FIG. 3, the wave shape 32 of a voltage falling over a defective actuator 10 is shown. The wave shape 32 first shows a regular electrical discharge and charge with corresponding falling and increasing flanks 34, 38 of a voltage pulse 40.

Directly after the voltage pulse 40, i.e. at the start of the time period in which the actuator 10 is located in the charged state, however, a temporary electrical breakdown 42 takes place which is expressed in a short-term voltage fall of a substantial degree and which results in a reduced actuator voltage during the time period between the voltage pulses 40. The reduced actuator voltage of the charged actuator 10 provides an indication of an electrical short circuit or a leakage current of the actuator 10.

Additionally or alternatively to the measurement of the voltage falling over the actuator 10, the operation of the actuator 10 can also be monitored by a continuous recording of the leakage current of the actuator 10. The measurement of the leakage current can take place by a current measurement device not shown in FIG. 1.

In FIG. 3, the time development of a leakage current of a piezoelectric actuator 10 is shown from its taking into operation up to its complete destruction after an operating period of 856 hours.

As can be seen from the Figure, only individual peaks 44 of leakage currents, e.g. after 30 hours, after 240 hours and after 270 hours, are detected during the first 480 operating hours. These individual leakage current peaks 44 are natural self-discharges which can also occur with a piezoelectric actuator 10 operating problem-free and cannot impair the operation of the actuator 10.

Only after an operating period of approximately 490 hours is an accumulated occurrence of leakage current peaks 46 able to be determined. These leakage current peaks 46 moreover have a substantially higher current strength than the natural leakage power peaks 44 occurring with an actuator 10 operating problem-free. The increased leakage current peaks 46 occur increasingly up to the final failure of the piezoelectric actuator 10. The significant accumulation of the increased leakage current peaks 46 after 490 operating hours therefore marks the arising of a defect in the piezoelectric actuator 10 which ultimately results in a failure of the actuator 10.

Since an accumulation of increased leakage current peaks 46 does not yet directly result in the destruction of the piezoelectric actuator 10, but rather indicates the start of an increasing worsening of the operation up to the complete failure of the actuator 10, the leakage current monitoring is also suitable for the detection of a defect in the actuator 10. The leakage current monitoring, like the voltage monitoring, in particular permits an early error recognition and thus a precise analysis of the error or of the error development and/or an early warning of a failure of the actuator 10.

1. A method for the monitoring and evaluation of the operation of a piezoelectric actuator comprising the steps of:
monitoring an electrical discharging process and an electrical charging process of the actuator over time and
evaluating the operation of the actuator based at least in part on the electrical discharging process and the electrical charging process with reference to the time course of the processes.

2. A method in accordance with claim 1, further comprising the steps of applying an electrical pulse current to the actuator, determining the time course of an electrical voltage falling over the actuator, comparing the wave shape of the determined voltage curve to a reference wave shape, and evaluating the operation of the actuator with reference to the comparison of the wave shape of the determined voltage curve with the reference wave shape.

3. A method in accordance with claim 2, further comprising the step of assessing the type of damage to the actuator based on the type of a deviation of the wave shape of the determined voltage curve relative to the reference wave shape.

4. A method in accordance with claim 1, further comprising the step of determining the time course of a leakage current of the actuator, wherein the step of evaluating the operation of the actuator is based at least in part on the time course of a leakage current of the actuator.

5. A method in accordance with claim 1, further comprising the step of storing the time course of the determined voltage and/or a determined leakage current of the actuator in a storage medium.

6. A method in accordance with claim 1, further comprising the step of producing a warning signal in response to the occurrence of one or more of:
(a) a deviation of the determined wave shape from the reference wave shape exceeding a predetermined value;
(b) an increase in leakage current of the actuator exceeding a predetermined magnitude; and/or
(c) an increase in leakage current of the actuator exceeding a predetermined frequency.

7. A method in accordance with claim 1, further comprising the step of applying a pulse width modulated current to the actuator.

8. An apparatus for the monitoring and evaluation of the operation of a piezoelectric actuator comprising:
a current source configured for applying an electrical pulse current to the actuator,
a measuring device configured for determining the time course of an electrical voltage falling over the actuator and/or of a leakage current of the actuator, and
an evaluation unit configured for evaluating the operation of the actuator by comparing the wave shape of the determined voltage curve relative to a reference wave shape or to the time course of the leakage current.

9. An apparatus in accordance with claim 8, further comprising a storage medium configured for storing the time course of the voltage and/or of the leakage current.

10. An apparatus in accordance with claim 8, further comprising a warning device configured for producing a warning signal exhibiting a predetermined form and indicating the occurrence of the occurrence of one or more of:
(a) a deviation of the determined wave shape from the reference wave shape exceeding a predetermined value;
(b) an increase in leakage current of the actuator exceeding a predetermined magnitude; and/or
(c) an increase in leakage current of the actuator exceeding a predetermined frequency.
